(19) United States
(12) Patent Application Publication
(10) Pub. No.: US 2011/0273213 A1
(43) Pub. Date: Nov. 10, 2011

(54) METHOD AND APPARATUS TO DYNAMICALLY ADJUST A CLOCK RATE IN A MOBILE DEVICE

(75) Inventor: Muraldhara Reddy Nandhimandalam Rama, San Diego, CA (US)

(73) Assignee: QUALCOMM Incorporated, San Diego, CA (US)

(21) Appl. No.: 12/775,071

(22) Filed: May 6, 2010

(51) Int. Cl. H03K 3/00

(52) U.S. Cl. 327/291

(57) ABSTRACT

In a particular embodiment, a method includes dynamically adjusting a clock rate to one or more hardware components within a mobile device during a silence period. During the silence period of a video telephony call, when a user of the mobile device is not speaking, the mobile device monitors the background noise and compares detected background noise data to previously detected background noise data to determine changes in the background noise. If the comparison shows that the change in background noise does not result in a change in background noise conditions or does not exceed a difference threshold, the clock rate to certain hardware components may be reduced and portions of certain hardware components may be powered down. The mobile device may send previously stored background noise update packets.

### FIELD

The present disclosure is generally related to a method and apparatus to dynamically adjust a clock rate in a mobile device during a packet switched video telephony (PSVT/CSVT) call.

### Description of Related Art

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and Internet Protocol (IP) telephones, can communicate voice and data packets over wireless networks. Many such wireless telephones incorporate additional devices to provide enhanced functionality for end users. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities.

As part of their computing capabilities, the portable computing devices may be configured to allow telephone calls and video telephone calls. During such calls, while one user talks, the other user's device may periodically send data related to its background noise condition. For example, in a video telephone call, a background noise update packet may be sent at least once in every 8 frames irrespective of background noise conditions. The repeated generation of the background noise update packet consumes power and utilizes data bandwidth.

### I. SUMMARY

A method and apparatus are disclosed to dynamically adjust a clock rate to one or more hardware components in a mobile device. During a silence period of a video telephony call, when a user of the mobile device is not speaking, the mobile device monitors a background noise and compares detected background noise data to previously detected background noise data to determine changes in the background noise. If the comparison shows that the change in background noise does not result in a change in background noise conditions or does not exceed a difference threshold, the clock rate to certain hardware components may be reduced and portions of certain hardware components may be powered down. For example, audio and video encoders may be powered down and may discontinue generation of background noise update packets. The mobile device may send previously stored background noise update packets. The background noise conditions will often not change enough to exceed the difference threshold during the telephone call. However, if the background noise conditions exceed the difference threshold, the clock rate to the hardware components may be reinstated to a standard operating clock rate and portions of hardware components that were powered down may be powered up to generate a new background noise update packet.

In a particular embodiment, a method includes dynamically adjusting a clock rate to a first hardware component within a mobile device during a silence period. The clock rate is dynamically adjusted in response to determining that a difference between a first background noise condition at the mobile device at a first time and a second background noise condition at the mobile device at a second time satisfies a difference threshold.

In another particular embodiment, an apparatus includes a background noise detection circuit configured to detect background noise. The apparatus further includes a background noise comparison circuit coupled to the background noise detection circuit. The background noise comparison circuit is configured to compare a first measured background noise detected at a first time with a second measured background noise detected at a second time to determine whether a difference between the first measured background noise and the second measured background noise satisfies a difference threshold. At least a portion of a time period between the first time and the second time occurs during a silence period. The apparatus further includes a clock rate controller configured to dynamically adjust a clock rate to one or more hardware components in response to determining that the difference satisfies the difference threshold.

One particular advantage provided by at least one of the disclosed embodiments is that power consumption of the mobile device may be reduced compared to mobile devices that continually generate new background noise packets during silence periods. The reduction in power consumption is made possible by sending stored background noise update packets rather than utilizing processing power to generate new background noise packets for transmission during the silence periods.

Other aspects, advantages, and features of the present disclosure will become apparent after review of the entire application, including the following sections: Brief Description of the Drawings, Detailed Description, and the Claims.

### II. BRIEF DESCRIPTION OF THE DRAWINGS

FIG. 1 is a block diagram of a particular illustrative embodiment of an apparatus to dynamically adjust a clock rate;

FIG. 2 is a block diagram of a second particular illustrative embodiment of an apparatus to dynamically adjust a clock rate;

FIG. 3 is a block diagram of a third particular illustrative embodiment of an apparatus to dynamically adjust a clock rate;

FIG. 4 is a block diagram of a fourth particular illustrative embodiment of an apparatus to dynamically adjust a clock rate;

FIG. 5 is a flow chart of a particular illustrative embodiment of a method of dynamically adjusting a clock rate;

FIG. 6 is a flow chart of a second particular illustrative embodiment of a method of dynamically adjusting a clock rate;

FIG. 7 is a flow chart of a third particular illustrative embodiment of a method of dynamically adjusting a clock rate; and

FIG. 8 is a flow chart of a fourth particular illustrative embodiment of a method of dynamically adjusting a clock rate.

### III. DETAILED DESCRIPTION

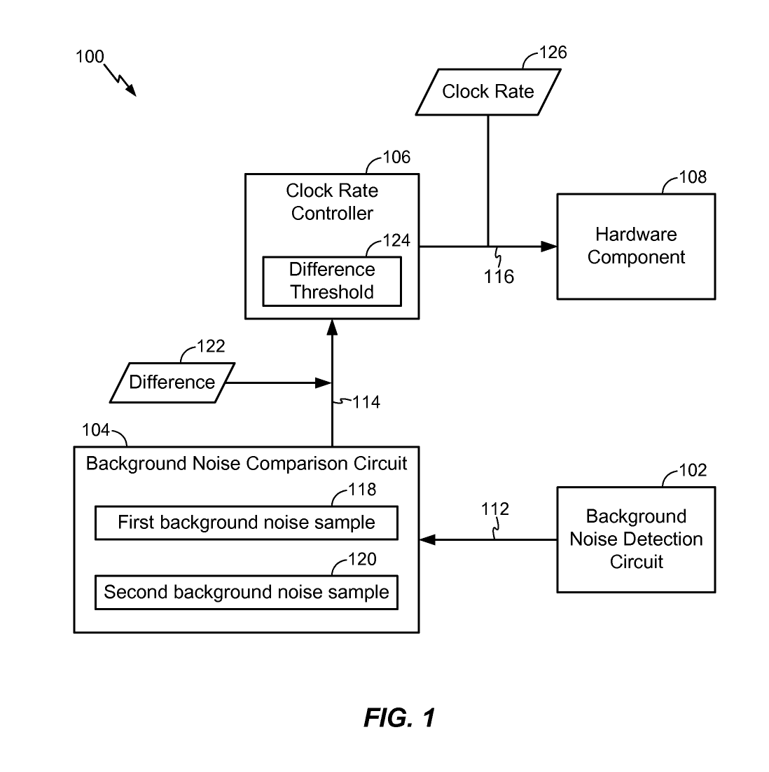

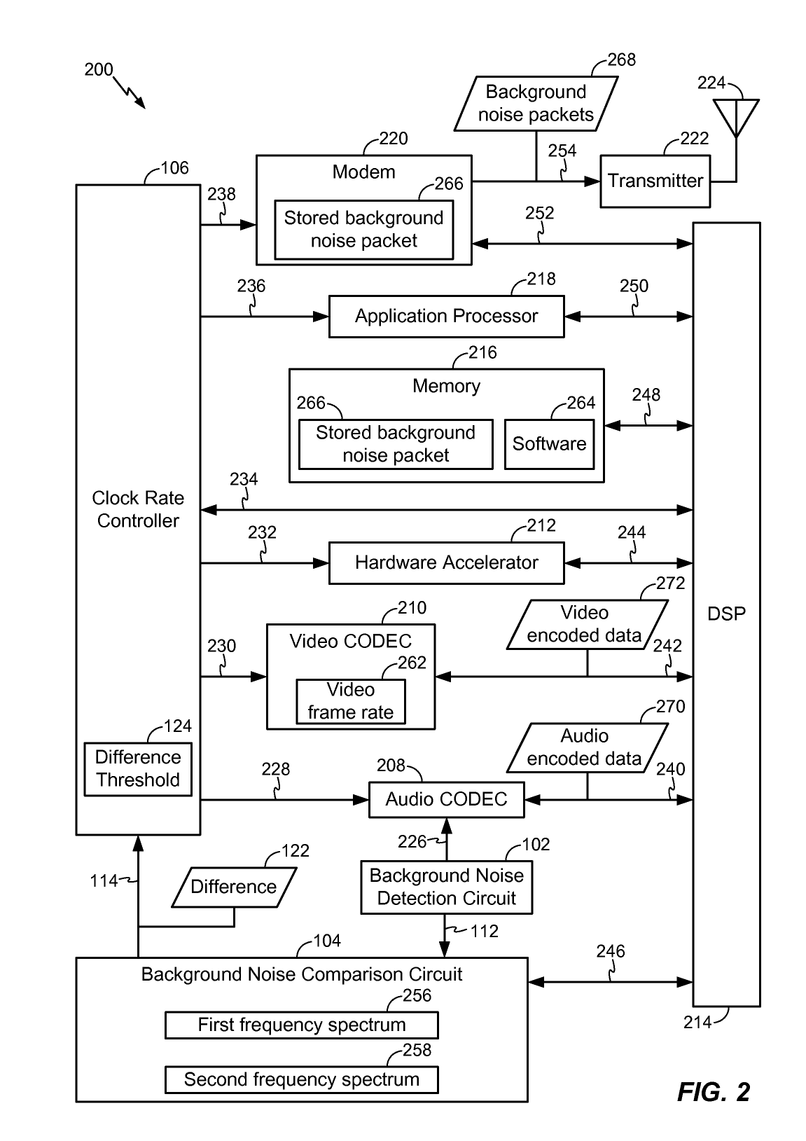

Referring to FIG. 1, a particular illustrative embodiment of an apparatus to dynamically adjust a clock rate to a hardware component during a silence period is disclosed and generally designated 100. The apparatus 100 includes a background noise detection circuit 102, a background noise comparison circuit 104, a clock rate controller 106, and a hardware component 108. While a single representative hardware component is shown in FIG. 1, the apparatus 100 may include multiple hardware components that are responsive to the clock rate controller 106, as will be described with respect to FIG. 2.

In a particular illustrative embodiment, the background noise detection circuit 102 detects background noise from the surrounding environment. Background noise is sampled and provided to the background noise comparison circuit 104 via a data path 112. The background noise comparison circuit 104 compares the detected background noise sample received from the background noise detection circuit 102 with historical background noise values and determines whether a difference 122 between the currently obtained background noise sample and the historical background noise values exceeds a difference threshold 124. The historical background noise values (hereinafter the “historical background noise sample”) may be a background noise sample received just prior to the current sample, a previously obtained sample, or a combination (e.g., average) of previously obtained samples. For example, the historical background noise sample may be a first background noise sample 118 and the current background noise sample may be a second background noise sample 120.

The average of the previously obtained samples may be an average of a set of the most recent samples (e.g., an average of the last ten background noise samples). Thus, the historical background noise sample may be updated to provide a current historical sample for comparison. In one illustrative embodiment, the historical background noise sample is only updated when the difference 122 exceeds the difference threshold 124. As a result, subsequent comparisons of newly obtained background noise samples are compared to the same background noise sample so long as the difference 122 does not exceed the difference threshold 124. In another illustrative embodiment, the historical background noise sample is updated after each comparison.

A result of the comparison is provided to the clock rate controller 106 via a data path 114. If the difference 122 resulting from the comparison exceeds the difference threshold 124 during the silence period, the clock rate controller 106 provides a clock rate 126 based on a normal operating clock rate to the hardware component 108 via a data path 116. The silence period is a period of time in which the mobile device is not receiving foreground audio input (e.g., the user of the mobile device is not talking during a video telephone session). If the difference 122 resulting from the comparison does not exceed the difference threshold 124 during the silence period, the clock rate controller 106 dynamically adjusts the clock rate 126 sent to the hardware component 108 via the data path 116. For example, the clock rate controller 106 may reduce the clock rate 126 sent to the hardware component 108 when the difference 122 does not exceed the difference threshold 124. Further, the hardware component 108, or a portion thereof, may be powered down when the difference 122 does not exceed the difference threshold 124.

The apparatus 100 may be implemented in a mobile device that relies on a portable power source, such as a rechargeable battery. As such, reducing power consumption by operation of the mobile device is desirable to extend an operational period between charges. The apparatus 100 may reduce the power consumption in the mobile device by reducing the clock rate to certain hardware components during silence periods so long as the difference threshold 124 is not exceeded. The clock rate may be reduced because the demand on certain hardware components and communication paths is reduced during the silence period when the difference threshold is not exceeded. For example, as will be described below with respect to FIG. 2, a background noise packet generation function may be disabled during the silence period when the difference threshold 124 is not exceeded and, instead, a previously generated background noise packet may be repeatedly sent to a remote device during the silence period. The demand on certain hardware components and data paths is reduced when the background noise packet generation function is disabled.

When the difference threshold 124 is exceeded during the silence period, a detectable change in background noise may have occurred, and the standard operating clock rate may be reinstated to enable generation of a new background noise packet generation. As a result, the power consumed by the mobile device is reduced during silence periods when the change in background noise does not exceed the difference threshold 124.

Referring to FIG. 2, a particular illustrative embodiment of an apparatus to dynamically adjust a clock rate to various hardware components in a mobile device during a silence period is disclosed and generally designated 200. The apparatus 200 includes the background noise detection circuit 102, the background noise comparison circuit 104, the clock rate controller 106, an audio CODEC 208 (i.e., an audio coder-decoder), a video CODEC 210 (i.e., a video coder-decoder), a hardware accelerator 212, a digital signal processor (DSP) 214, a memory 216, an application processor 218, a modem 220, a transmitter 222, and an antenna 224. While various hardware components are shown in FIG. 2, in other embodiments the apparatus 200 may include more or fewer hardware components than shown. The audio CODEC 208 and the video CODEC 210 may be implemented in hardware, software (i.e., by instructions executed by a processor, such as the DSP 214), or any combination thereof. The audio CODEC 208 and the video CODEC 210 may each include an encoder portion and a decoder portion in which each portion is controlled by a separate clock signal.

The DSP 214 is coupled to the various hardware components 208-220 and may be configured to monitor, control, provide instructions to, provide data to, and receive data from the various hardware components 208-220. For example, the DSP 214 may be coupled to the audio CODEC 208 via a data path 240, to the video CODEC 210 via a data path 242, to the hardware accelerator 212 via a data path 244, to the background noise comparison circuit 104 via a data path 246, to the memory 216 via a data path 248, to the application processor 218 via a data path 250, and to the modem 220 via a data path 252. The hardware accelerator 212 includes hardware that may be provided to replace one or more specific functions that would otherwise be performed in software. For example, the hardware accelerator may include a floating-point unit configured to carry out operations on floating point numbers (e.g., subtraction, addition, multiplication, division, and square root). The memory 216 may be a computer readable medium configured to store software 264. The software 264 may be executed by one or more of the hardware components, such as the audio CODEC 208, the video CODEC 210, the clock rate controller 106, the DSP 214, the application processor 218, and the modem 220, to perform one or more of the functions described herein.

In a particular illustrative embodiment, the background noise detection circuit 102 detects background noise from the surrounding environment. The detected background noise is sampled and provided to the background noise comparison circuit 104. The detected background noise may be sampled by the background noise detection circuit 102, the background noise comparison circuit 104, the audio CODEC 208, the DSP 214, or any combination thereof. The background noise comparison circuit 104 compares the detected background noise sample with the historical background noise sample and determines whether the difference 122 between the currently detected background noise sample and the historical background noise sample exceeds a difference threshold 124 during the silence period. The historical background noise sample may include a first frequency spectrum 256 of the historical background noise sampled over a frequency range and the detected background noise sample may include a second frequency spectrum 258 of the detected background noise sampled over the frequency range. The frequency range over which the background noise samples are compared may be limited to the human perceivable audio range (e.g., 12 hertz to 20,000 hertz), or a subset thereof. The background noise comparison circuit 104 of FIG. 2 may be configured to compare an amplitude, in decibels, of the first frequency spectrum 256 of the historical background noise sample to an amplitude of the second frequency spectrum 258 of the detected background noise sample. A result of the comparison may be provided to the DSP 214 via the data path 246 and to the clock rate controller 106 via a path 114.

If the difference 122 resulting from the comparison exceeds the difference threshold 124 during the silence period, the clock rate controller 106 maintains the standard operating clock rates to the various hardware components (i.e., the standard operating clock rates may correspond to clock rates applied to the hardware components in an audio processing mode in which the clock rates are not reduced, such as when the user of the mobile device is speaking) and a new background noise packet is generated from the current background noise sample and sent to the remote device. For example, the detected background noise may be provided to the audio CODEC 208 via a data path 226. The audio CODEC 208 may be configured to packetize samples of the background noise for transmission to a remote mobile device while the difference 122 between newly obtained background noise samples and the historical background noise sample continues to exceed the difference threshold 124. The generated background noise packets may be provided to the DSP 214 via the data path 240, and the DSP 214 may provide the detected background noise data packets to the modem 220 via the data path 252. The modem 220 may provide the background noise packets 268 to the transmitter 222 via a data path 254, and the transmitter 222 may transmit the background noise packets 268 using the antenna 224 to a remote device. Alternatively, the audio CODEC 208 may provide the packets directly to the modem 220. The background noise packets may be stored in the memory 216 as a stored background noise packet 266, in the modem 220 as the stored background noise packet 266, or any combination thereof.

If the difference 122 resulting from the comparison does not exceed the difference threshold 124, the clock rate controller 106 dynamically adjusts the clock rate, such as the clock rate 126 of FIG. 1, to certain hardware components, such that the adjusted clock rate is different from the standard operating clock rate. For example, the clock rate controller 106 may reduce the clock rate to at least a portion of the audio CODEC 208 via a data path 228, to at least a portion of the video CODEC 210 via a data path 230, to the hardware accelerator 212 via a data path 232, to the DSP 214 via a data path 234, to the application processor 218 via a data path 236, or any combination thereof, when the difference 122 does not exceed the difference threshold 124. The modem 220 may receive a clock signal from the clock rate controller 106 via a data path 238; however, in a particular embodiment the clock rate to the modem 220 is not reduced based on the comparison. Further, various hardware components, or portions thereof, may be powered down when the difference 122 does not exceed the difference threshold 124. For example, the components that may be powered down include a portion of the audio CODEC 208, a portion of the video CODEC 210, the application processor 218, or any combination thereof. The application processor 218 may receive a reduced clock signal or be powered down depending on the one or more applications it is running during the silence period. The hardware components, or portions thereof, that are powered down may be powered down by the clock rate controller 106, by the DSP 214, or any combination thereof.

When the audio CODEC 208 is provided with a reduced clock rate, or powered down, the background noise packet encoding functionality of the mobile device may be disabled. As such, the audio CODEC 208 ceases to generate background noise packets for transmission to the remote device, and instead, the apparatus 200 sends a previously stored background noise packet 266 to a remote device via the modem 220 and the transmitter 222. The previously stored background noise packet 266 may be stored at the memory 216 or at the modem 220. The previously stored background noise packet 266 may include video encoded data 272 provided by the video CODEC 210, audio encoded data 270 provided by the audio CODEC 208, or a combination thereof. The background noise detection circuit 102 continues to monitor background noise and the background noise comparison circuit 104 continues to compare measured background noise samples to the historical background noise sample after the clock rate is adjusted and/or after certain components are powered down. The previously stored background noise packet 266 may be repeatedly sent to the remote device according to a sending requirement while the difference 122 between newly obtained background noise samples and the historical background noise sample continues to remain below the difference threshold 124. If there are no previously stored background noise packets 266, the audio CODEC 208 may generate a new background noise packet prior to being powered down or reducing its clock rate. Alternatively, the audio CODEC 208 may generate a new background noise packet after the clock rate to the audio CODEC 208 is reduced.

When the difference 122 corresponding to a newly obtained background noise sample exceeds the difference threshold 124 after the clock rate to certain hardware components has been reduced, the clock rate controller 106 reinstates the standard operating clock rates to the hardware components whose clock rates were reduced. Further, the components that were powered down are powered up and their standard operating clock rates reinstated. As a result of the difference 122 exceeding the difference threshold 124, a new background noise packet may be generated by the audio CODEC 208, stored at the memory 216 and/or the modem 220, and transmitted to the remote device.

In addition to packets including audio data provided by the audio CODEC 208, the apparatus 200 of the mobile device may be configured to provide packets including video data from the video CODEC 210. For example, the apparatus 200 may be implemented in a mobile device that is configured to participate in a packet switched video telephony (PSVT) session using the video CODEC 210 to generate video packets. Further, the packet switched video telephony (PSVT) session may also be a packet switched video telephony and a circuit switched video telephony (PSVT/CSVT) session because the network over which the video data is communicated may include circuit switched components. When the video CODEC 210 is provided with a reduced clock rate, the video CODEC 210 may be configured to also reduce the video frame rate 262 of the video CODEC 210. Alternatively, if the clock rate of the video CODEC 210 is reduced, or a portion of the video CODEC 210 is powered down, the video CODEC 210 may be configured to no longer provide video packets for transmission to the remote device. Instead, a previously stored video packet, or a set of previously stored video packets, may be sent to the remote device via the modem 220 and the transmitter 222. The video packets may be stored at the memory 216 and/or the modem 220. The previously stored video packet, or set of packets, may be repeatedly sent to the remote device while the difference 122 between newly obtained background noise samples and the historical background noise sample continues to remain below the difference threshold 124. If there are no previously stored video packets, the video CODEC 210 may be configured to generate a new video packet prior to being powered down or reducing the clock rate to the video CODEC 210. Alternatively, the video CODEC 210 may generate a new video packet after the clock rate to the video CODEC 210 is reduced.

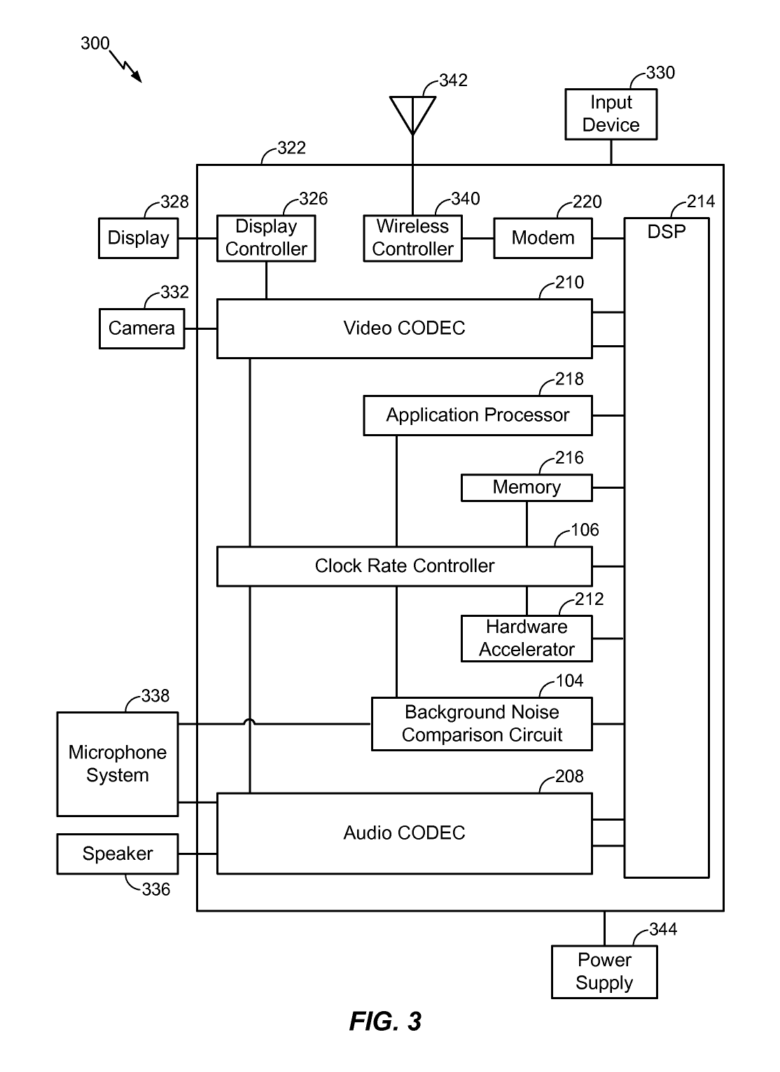

Referring to FIG. 3, a block diagram of a particular illustrative embodiment of an electronic device is depicted and generally designated 300. The device 300 may be a portable personal computing device, such as a mobile handset. The device 300 may include a processor, such as the digital signal processor (DSP) 214. The DSP 214 is coupled to the background noise comparison circuit 104, the audio CODEC 208, the video CODEC 210, the hardware accelerator 212, the clock rate controller 106, the memory 216, the application processor 218, and the modem 220.

FIG. 3 also shows a display controller 326 that is coupled to the video CODEC 210 and to a display 328. The video CODEC 210 may also be coupled to a video input device, such as a camera 332. The camera 332 may be used to take still pictures, record video, and participate in a packet switched video telephony session. The audio CODEC 208 may be coupled to an audio output device, such as a speaker 336, and one or more audio input devices, such as a microphone system 338. The microphone system 338 may be, for example, a dual microphone configuration that includes one microphone to capture foreground audio and another microphone to capture background noise. As another example, the microphone system 338 may be a quad microphone configuration, or a four channel microphone, that includes at least one microphone to capture foreground audio and at least two microphones to capture background noise. Alternatively, the microphone system 338 may include more or fewer microphones than in the dual or quad configurations described.

The microphone system 338 may also be coupled to the background noise comparison circuit 104 that compares measured samples of the background noise detected by the microphone system 338 to historic background noise samples. Data corresponding to the historic background noise samples may be stored at the memory 216. The background noise comparison circuit 104 may be configured to generate a difference between the detected background noise sample and the historic background noise sample. The difference may be provided to the clock rate controller 106. The difference may also be provided to the DSP 214. The background noise comparison circuit 104, the clock rate controller 106, the DSP 214, or any combination thereof, may be configured to compare the difference generated by the background noise comparison circuit 104 to the difference threshold. If the difference exceeds the difference threshold, the standard operating clock rates are provided by the clock rate controller 106 to the various hardware components and a new background noise packet is generated by the audio CODEC 208 for transmission to the remote device.

In a particular embodiment, the difference threshold value is provided as a default value and may be adjusted by a user, either directly or indirectly, via the input device 330, the display 328 (e.g., if used as a touch screen input device), the speaker 336 (e.g., if used as a speech recognition input device), or any combination thereof. For example, a user may directly adjust the difference threshold value by selecting a new value from a menu provided via the display 328. The user may indirectly adjust the difference threshold by selecting different system configurations. For example, the user may select a reduced power system configuration to reduce power consumption from a power supply 344. A lower power configuration would typically have a large difference threshold value to increase a likelihood that the various components, or portions thereof, of the electronic device 300 would have a reduced clock rate or be powered down during the silence period.

FIG. 3 also indicates that a wireless controller 340 can be coupled to the digital signal processor 214 via the modem 220 and to a wireless antenna 342. In a particular embodiment, the DSP 214, the display controller 326, the memory 216, the audio CODEC 208, the video CODEC 210, the hardware accelerator 212, the application processor 218, and the background noise comparison circuit 104 are included in a system-in-package or system-on-chip device 322. In a particular embodiment, the input device 330 and the power supply 344 are coupled to the system-on-chip device 322. Moreover, in a particular embodiment, as illustrated in FIG. 3, the display 328, the camera 332, the input device 330, the speaker 336, the microphone system 338, the wireless antenna 342, and the power supply 344 are external to the system-on-chip device 322. However, each of the display 328, the camera 332, the input device 330, the speaker 336, the microphone system 338, the wireless antenna 342, and the power supply 344 can be coupled to a component of the system-on-chip device 322, such as an interface or a controller.

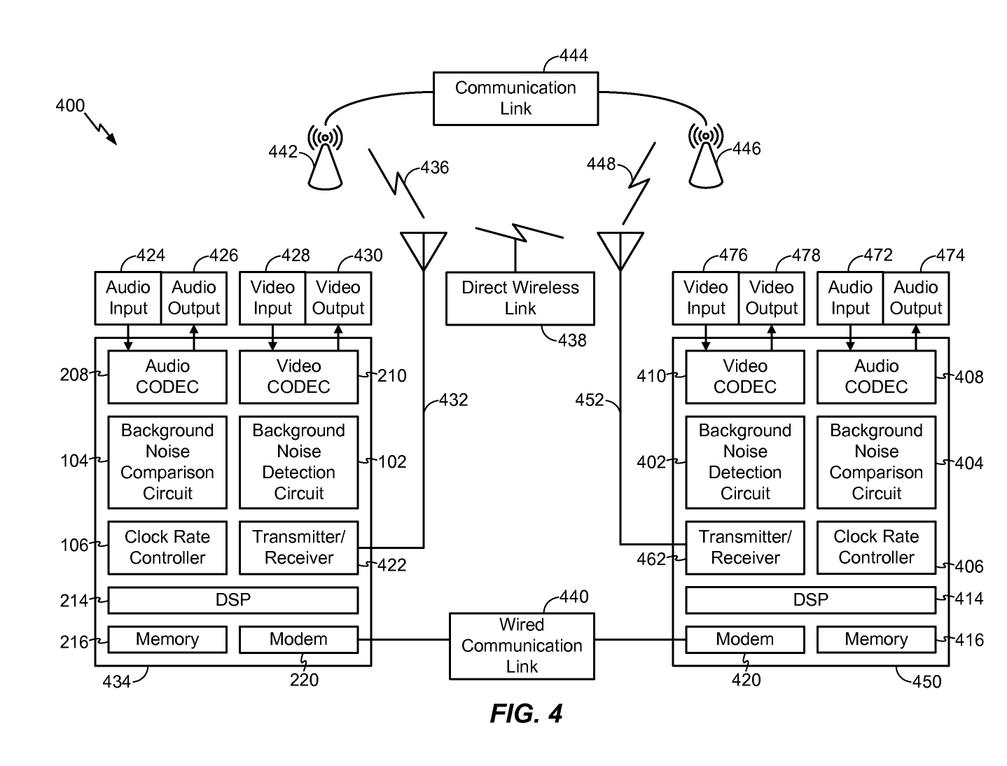

Referring to FIG. 4, a block diagram of a particular illustrative embodiment of a communication system is depicted and generally designated 400. The system 400 includes a first mobile device 434 and a second mobile device 450 configured to communicate with one another. The first mobile device 434 includes the background noise detection circuit 102, the background noise comparison circuit 104, the clock rate controller 106, the audio CODEC 208, the video CODEC 210, the DSP 214, the memory 216, the modem 220, and a transmitter/receiver 422. The audio CODEC 208 and the background noise comparison circuit 104 are coupled to the background noise detection circuit 102 (e.g., at least one background microphone). The background noise detection circuit 102 may be configured to detect and sample the background noise in the surrounding environment. The audio CODEC 208 is coupled to an audio input 424 (e.g., a foreground microphone) and an audio output 426 (e.g., a speaker). The video CODEC 210 is coupled to a video input 428 (e.g., a camera) and a video output 430 (e.g., a video display). The transmitter/receiver 422 is coupled to an antenna 432 and configured to send and receive data.

The second mobile device 450 includes a background noise detection circuit 402, a background noise comparison circuit 404, a clock rate controller 406, an audio CODEC 408, a video CODEC 410, a DSP 414, a memory 416, a modem 420, and a transmitter/receiver 462. The audio CODEC 408 and the background noise comparison circuit 404 are coupled to a background noise detection circuit 402 (e.g., at least one background microphone). The background noise detection circuit 402 may be configured to detect and sample the background noise in the surrounding environment. The audio CODEC 408 is coupled to an audio input 472 (e.g., a microphone system) and an audio output 474 (e.g., a speaker). The video CODEC 410 is coupled to a video input 476 (e.g., a camera) and a video output 478 (e.g., a video display). The transmitter/receiver 462 is coupled to an antenna 452 and configured to send and receive data.

The first mobile device 434 and the second mobile device 450 may be configured to communicate via a communication link, such as a communication link 444. To transmit data, the modem 220 may be configured to prepare data for transmission and to provide the data to the transmitter/receiver 422. The transmitter/receiver 422 sends data over a first wireless link 436 using the antenna 432 to an antenna 442 coupled to communication equipment. The data transmitted to the antenna 442 is provided to an antenna 446 and its corresponding communication equipment via the communication link 444. The data received over the communication link 444 may be transmitted over a second wireless link 448 to the antenna 452 of the second mobile device 450. The first wireless link 436 and the second wireless link 448 may be configured to utilize one or more of the Institute of Electrical and Electronics Engineers (IEEE) 802 standards such as IEEE 802.11 (wireless local area network (WLAN)), IEEE 802.15 (personal area network (PAN), including Bluetooth and ZigBee), IEEE 802.16 (worldwide interoperability for microwave access (WiMAX)), IEEE 802.20 (mobile broadband wireless access (MBWA)), IEEE 802.22 (wireless regional area network (WRAN)), and Ultra-wideband (UWB). The communication link 444 may be a wireless communication link, a wired communication link, or a combination thereof. The communication link 444 may be part of a cellular network, a circuit switched telephone network, such as a public switched telephone network, a packet switched network, including the Internet, a satellite communication network, or any combination thereof.

The first mobile device 434 and the second mobile device 450 may be configured to communicate via a wired communication link 440. The wired communication link 440 may be part of a circuit switched telephone network, such as a public switched telephone network, a packet switched network, including the Internet, or any combination thereof. Further, the first mobile device 434 and the second mobile device 450 may be configured to communicate directly via a direct wireless communication link 438.

In a particular embodiment, the first mobile device 434 and the second mobile device 450 may be communicating with one another in a packet switched video telephone session in which audio and video data is transmitted between mobile devices. The audio inputs 424 and 472, and the video inputs 428 and 476, collect audio and video data for transmission to the other remote device. The audio and video data received from the first mobile device 434 at the second mobile device 450 is provided to the audio output 474 and the video output 478, respectively. Likewise, the audio and video data received from the second mobile device 450 at the first mobile device 434 is provided to the audio output 426 and the video output 430, respectively. During the video telephone session, the first mobile device 434 enters a silence period in which the first mobile device 434 is not receiving foreground audio input at the audio input 424.

During the silence period, the background noise detection circuit 102 detects background noise in the surrounding environment. The detected background noise is sampled and compared to the historical background noise sample at the background noise comparison circuit 104. The difference is generated by the background noise comparison circuit 104 and may be provided to the clock rate controller 106. The difference may also be provided to the DSP 214. The background noise comparison circuit 104, the clock rate controller 106, the DSP 214, or any combination thereof, may be configured to compare the difference generated by the background noise comparison circuit 104 to the difference threshold. If the difference exceeds the difference threshold, the standard operating clock rates are provided by the clock rate controller 106 to the various hardware components and a new background noise packet is generated from the background noise sample by the audio CODEC 208 for transmission to the second mobile device 450. Further, the video CODEC 210 continues to generate updated video packets for transmission to the second mobile device 450. At the second mobile device 450, the background noise packet received from the first mobile device 434 is decoded at the audio CODEC 408 and broadcast via the audio output 474. In addition, the received video packets are decoded at the video CODEC 410 and displayed at the video output 478.

If the difference does not exceed the difference threshold during the silence period, a reduced clock rate may be provided to various components from the clock rate controller 106. For example, the clock rate may be reduced to the DSP 214, at least a portion of the audio CODEC 208, at least a portion of the video CODEC 210, or any combination thereof. Further, a portion of the audio CODEC 208, a portion of the video CODEC 210, or any combination thereof, may be powered down. For example, the encoder portion of the audio and video CODECs, 208 and 210, may be powered down. Also, the decoder portions of the audio and video CODECs, 208 and 210, may receive a reduced clock rate. In addition to reducing the clock rate or powering down portions of hardware components, a previously sent background noise packet, such as the stored background noise packet 266 stored at the memory 216 or at the modem 220 in FIG. 2, may be sent to the second mobile device 450 when the difference does not exceed the difference threshold. In this scenario, the audio CODEC 208 will not have to generate a background noise packet for transmission to the second mobile device 450. The first mobile device 434 will continue to detect the background noise, compare the detected background noise to the historical background noise sample, and repeatedly send the previously sent background noise packet to the second mobile device 450 while the difference does not exceed the difference threshold. The second mobile device 450 receives and decodes the background noise packet and broadcasts the background noise via the audio output 474.

In addition, a previously sent video packet, or packets, stored at the memory 216, or the modem 220 may be sent in place of newly generated video packets. Therefore, the video CODEC 210 will not have to generate a new video packet for transmission to the second mobile device 450. Alternatively, the video CODEC 210 may continue to generate new video packets, but at a reduced frame rate. The second mobile device 450 receives and decodes the video packets and displays the resulting video at the video output 478.

When a change in the detected background noise occurs that is substantial enough to cause the difference to exceed the difference threshold while the clock rate controller 106 is providing the reduced clock rate to one or more hardware components, the clock rate controller 106 reinstates the standard operating clock rate. Reinstating the clock rate enables the audio CODEC 208 to generate a new background noise packet to send to the second mobile device 450 and enables the video CODEC 210 to generate new video packets at a normal frame rate to send to the second mobile device 450.

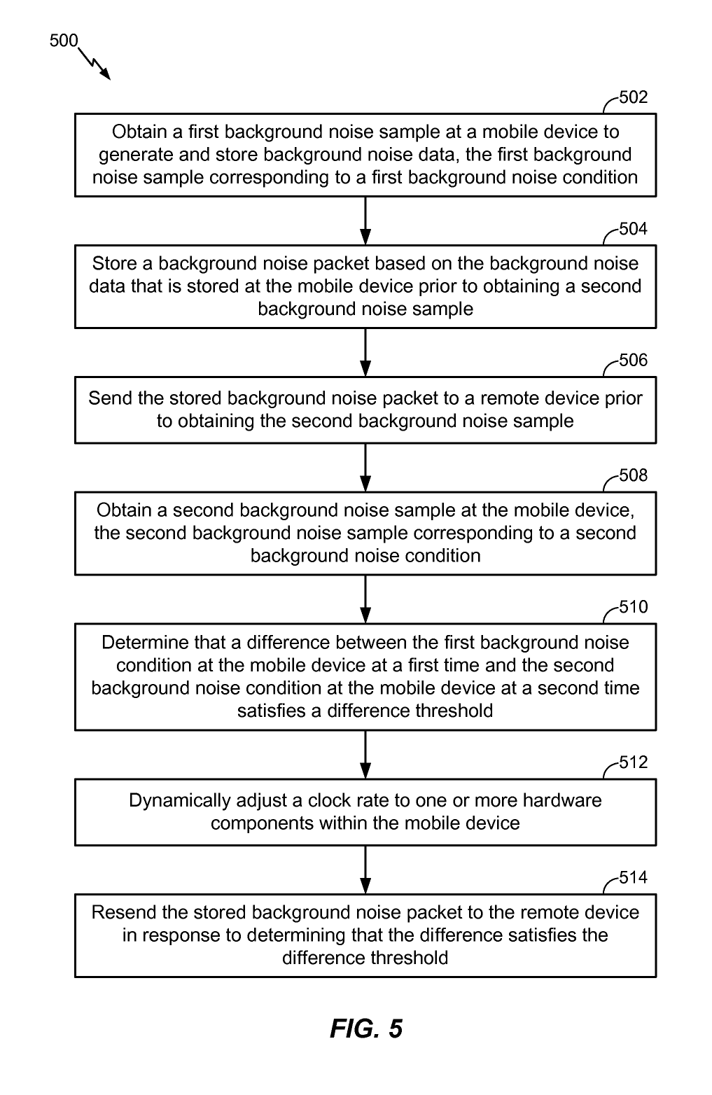

Referring to FIG. 5, a particular embodiment of a method 500 is illustrated. The method 500 may include obtaining a first background noise sample at a mobile device to generate and store background noise data, the first background noise sample corresponding to a first background noise condition, at 502. For example, the background noise detection circuit 102 of FIG. 2 may be configured to detect background noise. The detected background noise may be sampled by the background noise detection circuit 102, the background noise comparison circuit 104, the audio CODEC 208, or any combination thereof. From the background noise sample, data may be generated and stored in the memory 216. The first background noise condition corresponding to the first background noise sample 118 may be a particular type of background noise, noise environment, noise level, or any combination thereof.

A background noise packet may be stored based on the background noise data that is stored at the mobile device prior to obtaining a second background noise sample, at 504. For example, prior to obtaining another background noise sample, the audio CODEC 208 of FIG. 2 may be configured to generate a background noise packet from the background noise data stored at the memory 216.

The method 500 may further include sending the stored background noise packet to a remote device prior to obtaining the second background noise sample, at 506. For example, prior to obtaining another background noise sample, the stored background noise packet 266 of FIG. 2 is prepared by the modem 220 for sending to the remote device and then transmitted to the remote device via the transmitter 222 and the antenna 224.

The method 500 may further include obtaining a second background noise sample at the mobile device, the second background noise sample corresponding to a second background noise condition, at 508. For example, the background noise detection circuit 102 of FIG. 2 continues to detect background noise from which samples are taken. A change in the background noise creates a new background noise condition and a background noise sample is taken during the new condition. An example of a change in background noise condition might include a first background noise condition created when the mobile device is operating outside in a crowd. A second background noise condition may be created when a train passes nearby the crowd where the mobile device is located.

The method 500 may further include determining that a difference between the first background noise condition at the mobile device at a first time and the second background noise condition at the mobile device at a second time satisfies a difference threshold, at 510. For example, the background noise comparison circuit 104 of FIG. 2 determines the difference between the first background noise condition and the second background noise condition by comparing the stored background noise data of the first background noise sample 118 to the background noise data of the second background noise sample 120. The difference determined by the background noise comparison circuit 104 may be compared to the difference threshold. The comparison to the difference threshold may be performed by the DSP 214, the clock rate controller 106, the background noise comparison circuit 104, or any combination thereof. In a particular embodiment, if the determined difference is less than the difference threshold, the difference threshold is satisfied. When the difference threshold is not satisfied, the change in background noise from the first condition to the second condition is not great enough to exceed the difference threshold.

In response to determining that the difference threshold is satisfied, the method 500 proceeds by dynamically adjusting a clock rate to one or more hardware components within the mobile device, at 512. For example, the clock rate controller 106 of FIG. 2 may be configured to reduce the clock rate to at least a portion of the audio CODEC 208, at least a portion of the video CODEC 210, the hardware accelerator 212, the DSP 214, the application processor 218, or any combination thereof.

The method 500 may further include resending the stored background noise packet to the remote device in response to determining that the difference satisfies the difference threshold, at 514. For example, the modem 220 of FIG. 4 may be configured to resend the background noise packet stored at the modem 220 or the memory 216. Because the packet being sent already exists in a stored location, the encoder portion of the audio CODEC 208 does not need to create a new background noise packet. The stored background noise packet may repeatedly be resent while the difference threshold remains satisfied. To send the background noise packet, the modem 220 provides a properly formatted packet to the transmitter/receiver 442 that may use the antenna 432 to transmit the packet to a remote device, such as the second mobile device 450, via the communication link 444.

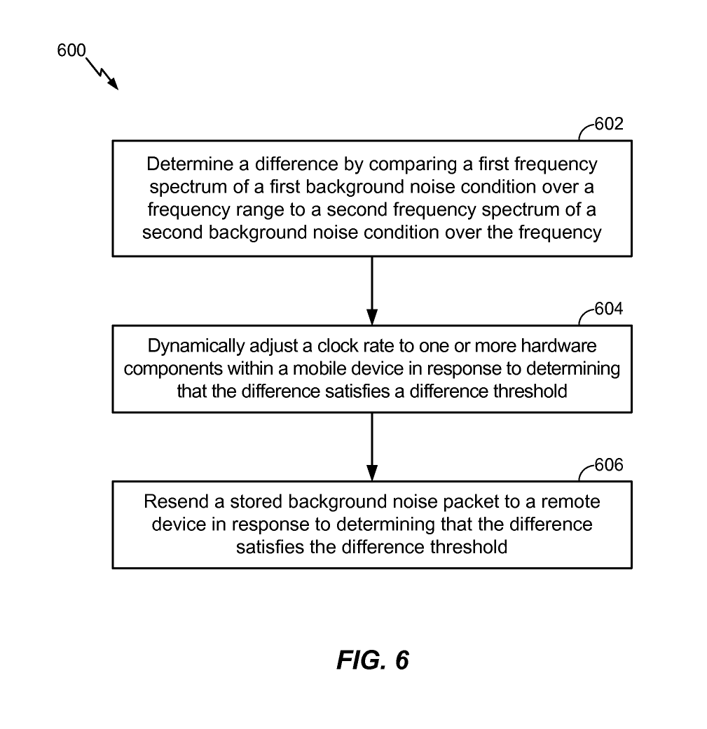

Referring to FIG. 6, a particular embodiment of a method 600 is illustrated. The method 600 includes determining a difference by comparing a first frequency spectrum of a first background noise condition over a frequency range to a second frequency spectrum of a second background noise condition over the frequency range, at 602. For example, the background noise comparison circuit 104 of FIG. 2 may be configured to compare an amplitude, in decibels, of the first frequency spectrum 256 of the stored first sample to an amplitude of the second frequency spectrum 258 of the second sample. The frequency range over which the background noise samples are compared may be limited to the human perceivable audio range (e.g., 12 hertz to 20,000 hertz), or a subset thereof

The method 600 further includes dynamically adjusting a clock rate to one or more hardware components within a mobile device in response to determining that the difference satisfies a difference threshold, at 604. For example, after it is determined that the difference between the amplitudes of the first and second frequency spectrums 256 and 258 of FIG. 2 do not exceed a difference threshold, the clock rate controller 106 may be configured to reduce the clock rate to at least a portion of the audio CODEC 208, at least a portion of the video CODEC 210, the hardware accelerator 212, the DSP 214, the application processor 218, or any combination thereof.

The method 600 further includes resending a stored background noise packet to a remote device in response to determining that the difference satisfies the difference threshold, at 606. For example, the modem 220 of FIG. 4 may be configured to resend the background noise packet stored at the modem 220 or the memory 216. Because the packet being sent already exists in a stored location, the encoder portion of the audio CODEC 208 does not need to create a new background noise packet. The stored background noise packet may be repeatedly resent while the difference threshold is satisfied.

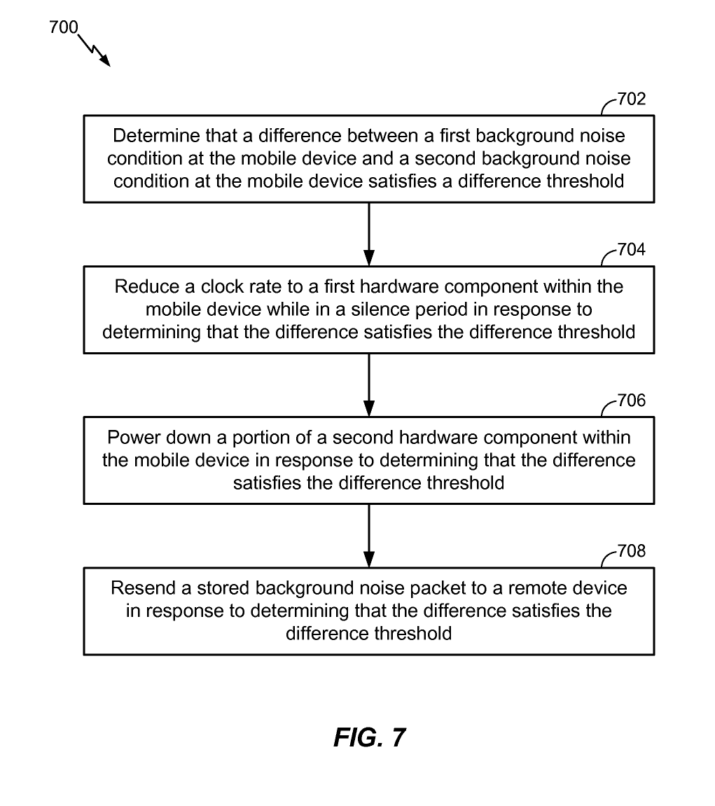

Referring to FIG. 7, a particular embodiment of a method 700 is illustrated. The method 700 includes determining that a difference between a first background noise condition at the mobile device and a second background noise condition at the mobile device satisfies a difference threshold, at 702. For example, the background noise comparison circuit 104 of FIG. 2 determines the difference between the first background noise condition and the second background noise condition by comparing the stored background noise data of the first background noise sample 118 to the background noise data of the second background noise sample 120. The difference determined by the background noise comparison circuit 104 may be compared to the difference threshold. For example, the difference threshold may be satisfied if the determined difference is less than the difference threshold.

The method 700 further includes reducing a clock rate to a first hardware component within the mobile device while in a silence period in response to determining that the difference satisfies the difference threshold, at 704. For example, the clock rate controller 106 of FIG. 2 may be configured to reduce the clock rate to at least a portion of the audio CODEC 208, at least a portion of the video CODEC 210, the hardware accelerator 212, the DSP 214, the application processor 218, or any combination thereof. The reduced clock rate to the hardware components continues so long as the difference continues to satisfy the difference threshold during a silence period. If the silence period ends or the difference exceeds the difference threshold, the clock rate controller 106 may reinstate the standard operating clock rates.

In addition to reducing the clock rate to the first hardware component, the method 700 may also include powering down at least a portion of a second hardware component (or other components) within the mobile device in response to determining that the difference satisfies the difference threshold, at 706. For example, the background noise comparison circuit 104 of FIG. 2, the clock rate controller 106, the DSP 214, or any combination thereof, may be configured to power down a portion of the audio CODEC 208, a portion of the video CODEC 210, the application processor 218, or any combination thereof. The portion of the CODECs 208 and 210, that may be powered down includes the encoder portion. The powered down portions may stay powered down so long as the difference continues to satisfy the difference threshold during a silence period. If the silence period ends or the difference exceeds the difference threshold, the powered down portions are powered up.

The method 700 further includes resending a stored background noise packet to a remote device in response to determining that the difference satisfies the difference threshold, at 708. For example, the modem 220 of FIG. 4 may be configured to resend the background noise packet stored at the modem 220 or at the memory 216. Since the packet being sent already exists in a stored location, the encoder portion of the audio CODEC 208 does not need to create a new background noise packet. The stored background noise packet may be repeatedly resent while the difference threshold is satisfied.

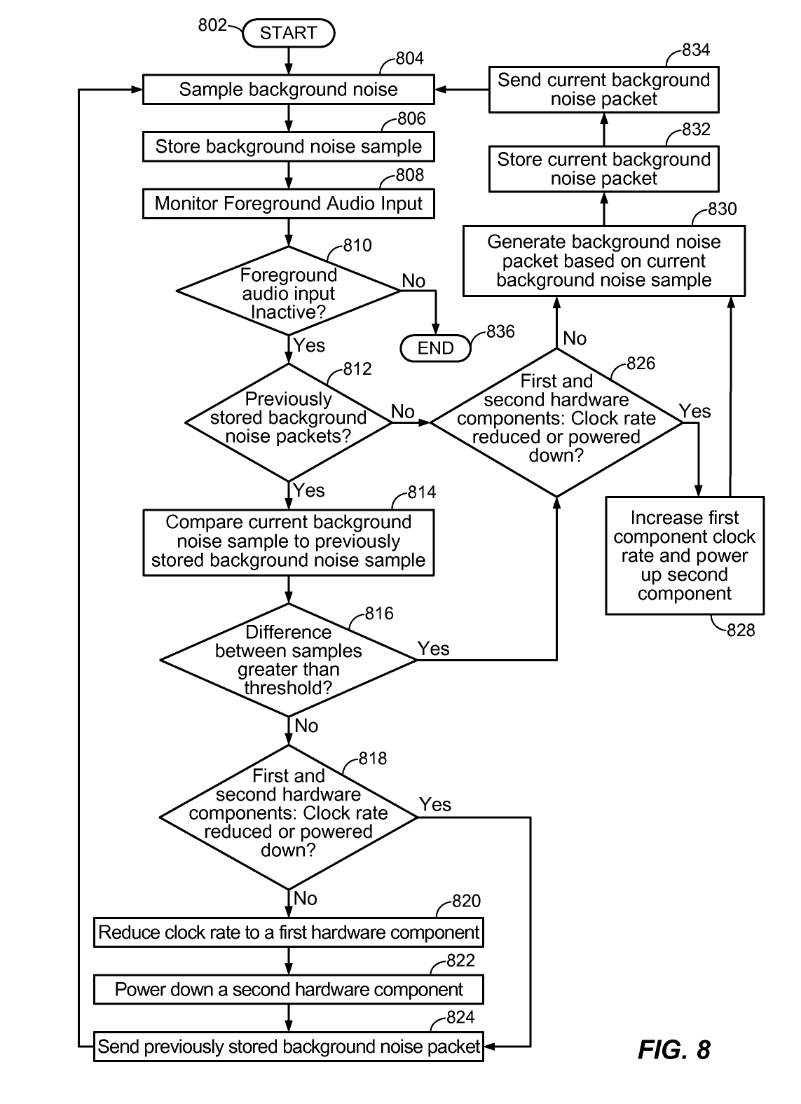

Referring to FIG. 8, a particular embodiment of a method 800 is illustrated. The method 800 starts, at 802, and includes sampling the background noise, at 804. For example, the background noise detection circuit 102 of FIG. 2 may detect background noise and the detected background noise may be sampled by the background noise detection circuit 102, the background noise comparison circuit 104, the audio CODEC 208, the DSP 214, or any combination thereof.

The method 800 further includes storing the background noise sample, at 806. For example, the data comprising the background noise sample may be stored at the memory 216 or at the modem 220. At 808, a foreground audio input is monitored. The foreground audio input is monitored to determine whether the mobile device is in a silence period. For example, the audio input 424 of FIG. 4 may be monitored by the audio CODEC 208 or the DSP 214 to determine whether the audio input 424 is inactive, at 810. For example, the audio input 424 may be considered inactive when the foreground audio input does not detect the speaker's voice (e.g., the foreground audio at the foreground audio input does not exceed a threshold). If the audio input is active, the method 800 ends, at 836. However, if the audio input is inactive, the method 800 continues by determining whether there are any previously stored background noise packets, at 812.

If it is determined that there are no previously stored background noise packets, the method 800 continues to 826. However, if it is determined that there are previously stored background noise packets, the method 800 continues by comparing the current background noise sample to the previously stored background noise sample, at 814. For example, the background noise comparison circuit 104 of FIG. 2 may be configured to compare a current background noise sample to the previously stored background noise sample to determine a difference. At 816, if the difference between samples is greater than a threshold, the method 800 continues to 826. However, if the difference between samples is not greater than the threshold, the method 800 continues to 818, where it is determined whether the first hardware component has a reduced clock rate or the second hardware component is powered down. If the first hardware component does not have a reduced clock rate or the second hardware component is not powered down, the method 800 continues to 820 by reducing the clock rate to the first hardware component, at 820 and by powering down the second hardware component, at 822. The method 800 continues by sending the previously stored background noise packet to a remote device, at 824.

Returning to 818, if the first hardware component does have a reduced clock rate and the second hardware component is powered down, the method 800 continues by sending the previously stored background noise packet to the remote device, at 824. For example, the modem 220 of FIG. 4 may be configured to send the previously stored background noise packet. Because the packet being sent already exists in a stored location, the encoder portion of the audio CODEC 208 does not need to create a new background noise packet. To send the background noise packet, the modem 220 provides a properly formatted packet to the transmitter/receiver 442 that uses the antenna 432 to transmit the packet to the remote device. The method 800 returns to 804, where the background noise is sampled.

At 826, it is determined whether the first hardware component has a reduced clock rate or the second hardware component is powered down. If the first hardware component does have a reduced clock rate or the second hardware component is powered down, the method 800 continues to 828 by increasing the first component clock rate and powering up the second component. For example, the clock rate controller 106 of FIG. 2 may be configured to increase the clock rate to the first hardware component. Also, the clock rate controller 106, the DSP 214, or any combination thereof, may be configured to power up the second hardware component.

After increasing the first component clock rate and powering up the second component, at 828, or determining that the first hardware component does not have a reduced clock rate or the second hardware component is not powered down, the method 800 continues to 830 by generating a new background noise packet based on the current background noise sample. For example, the audio CODEC 208 of FIG. 2 may be configured to generate a new background noise packet based on the current background noise sample. The method 800 further includes storing the background noise packet, at 832, and sending the current background noise packet to the remote device, at 834. For example, the background noise packet may be stored at the memory 216, the modem 220, or any combination thereof. To send the background noise packet, the modem 220 of FIG. 4 provides a properly formatted packet to the transmitter/receiver 442 that uses an antenna 432 to transmit the packet to the remote device. The method 800 returns to 804, where the background noise is sampled.

Those of skill would further appreciate that the various illustrative logical blocks, configurations, modules, circuits, and algorithm steps described in connection with the embodiments disclosed herein may be implemented as electronic hardware, computer software, or combinations of both. Various illustrative components, blocks, configurations, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. A method comprising:
dynamically adjusting a clock rate to a first hardware component within a mobile device while in a silence period in response to determining that a difference between a first background noise condition at the mobile device at a first time and a second background noise condition at the mobile device at a second time satisfies a difference threshold.

2. The method of claim 1, wherein the silence period occurs when the mobile device is not transmitting foreground audio data.

3. The method of claim 1, wherein the difference threshold is satisfied when the difference is less than the difference threshold.

4. The method of claim 1, wherein the first background noise condition corresponds to a first background noise sample and wherein the second background noise condition corresponds to a second background noise sample, and further comprising:
storing a background noise packet based on background noise data that is stored at the mobile device prior to obtaining the second background noise sample; and
sending the stored background noise packet to a remote device prior to obtaining the second background noise sample.

5. The method of claim 4, wherein the background noise packet is stored at a modem.

6. The method of claim 4, further comprising:
obtaining the second background noise sample at the mobile device;
determining that the difference between the first background noise condition at the mobile device and the second background noise condition at the mobile device satisfies the difference threshold; and
resending the stored background noise packet to the remote device in response to determining that the difference satisfies the difference threshold.

7. The method of claim 6, wherein the stored background noise packet comprises video encoded data, audio encoded data, or any combination thereof.

8. The method of claim 1, wherein dynamically adjusting the clock rate to the first hardware component comprises reducing the clock rate to the first hardware component.

9. The method of claim 8, wherein a portion of a second hardware component is powered down in response to determining that the difference satisfies the difference threshold.

10. The method of claim 9, wherein the first hardware component comprises a digital signal processor (DSP), a hardware accelerator, an application processor, or any combination thereof, and wherein the second hardware component comprises a video coder-decoder, an audio coder-decoder, or any combination thereof.

11. The method of claim 1, wherein the difference is determined in conjunction with a packet switched video telephony session, and wherein dynamically adjusting the clock rate includes reducing the clock rate and reducing a video frame rate of a video coder-decoder at the mobile device.

12. The method of claim 1, further comprising disabling background noise packet encoding at the mobile device in response to determining that the difference satisfies the difference threshold.

13. The method of claim 1, wherein the difference threshold is satisfied when a first frequency spectrum of the first background noise condition over a frequency range does not differ from a second frequency spectrum of the second background noise condition over the frequency range by more than a predetermined amount.

14. An apparatus comprising:
a background noise detection circuit configured to detect background noise;
a background noise comparison circuit coupled to the background noise detection circuit, the background noise comparison circuit configured to compare first background noise detected at a first time with second background noise detected at a second time to determine whether a difference between the first background noise and the second background noise satisfies a difference threshold, wherein at least a portion of a time period between the first time and the second time occurs during a silence period; and
a clock rate controller configured to dynamically adjust a clock rate to a hardware component in response to determining that the difference satisfies the difference threshold.

15. The apparatus of claim 14, wherein the silence period occurs when the transmitter is not transmitting foreground audio data.

16. The apparatus of claim 14, wherein the clock rate to the hardware component is reduced during the silence period.

17. The apparatus of claim 16, wherein the hardware component is a video coder-decoder, an audio coder-decoder, a digital signal processor (DSP), a hardware accelerator, an application processor, or any combination thereof.

18. The apparatus of claim 14, further comprising:
a memory configured to store a background noise packet based on background noise data that is stored at the memory prior to detecting the second background noise;
a transmitter; and
a modem configured to resend the stored background noise packet to a remote device via the transmitter during the silence period.

19. The apparatus of claim 14, wherein the background noise comparison circuit is configured to determine the difference by comparing a first frequency spectrum of the first background noise over a frequency range to a second frequency spectrum of the second background noise over the frequency range.

20. The apparatus of claim 14, wherein the background noise comparison circuit and the clock rate controller are integrated in a mobile handset.

21. An apparatus comprising:
means for dynamically adjusting a clock rate to a hardware component within a mobile device in response to determining that a difference between a first background noise condition at the mobile device at a first time and a second background noise condition at the mobile device at a second time satisfies a difference threshold, wherein the first background noise condition corresponds to a first background noise sample and wherein the second background noise condition corresponds to a second background noise sample; and
means for storing a background noise packet to be sent while the clock rate to the hardware component is reduced, the background noise packet based on background noise data that is stored at the mobile device prior to detecting the second background noise sample.

22. The apparatus of claim 21 integrated in a mobile handset.

23. The apparatus of claim 21, further comprising means for repeatedly resending the background noise packet to a remote device in response to determining that the difference satisfies the difference threshold.

24. A computer readable medium storing computer executable code comprising:
code for dynamically adjusting a clock rate to a hardware component within a mobile device in response to determining that a difference between a first background noise condition at the mobile device at a first time and a second background noise condition at the mobile device at a second time satisfies a difference threshold.

25. The computer readable medium of claim 24, wherein the first background noise condition corresponds to a first background noise sample and wherein the second background noise condition corresponds to a second background noise sample, and further comprising code for sending a background noise packet based on background noise data that is stored at the mobile device.

26. The computer readable medium of claim 25, further comprising code for storing the background noise packet at a modem.

27. The computer readable medium of claim 25, further comprising code for repeatedly resending the background noise packet in response to determining that the difference satisfies the difference threshold.

28. The computer readable medium of claim 24, further comprising code for disabling additional background noise packet encoding at the mobile device in response to determining that the difference satisfies the difference threshold.
